(19) United States
(12) Patent Application Publication
(10) Pub. No.: US 2007/0215462 A1
(43) Pub. Date: Sep. 20, 2007

(54) Target holding apparatus

(75) Inventors: Wolfram Beele, Ratingen (DE); Gerald Eschendorff, TE Venlo (NL)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sulzer Metco AG, Wohlen (CH)

(21) Appl. No.: 11/724,045

(22) Filed: Mar. 13, 2007

(30) Foreign Application Priority Data
Mar. 16, 2006 (EP) 06405117.0

(51) Int. Cl. C23C 14/00

(52) U.S. Cl. 204/298.02

(57) ABSTRACT

An apparatus for the attachment of a target or target segment (9) of a coating source includes a target or target segment (9) and a target holder (1) which includes a cooling body (3) and connecting means (6,7,8,11) for the attachment of the target or target segment to the cooling body. The connecting means include (3,6,7,8,10,11) electrically and/or thermally conductive means, so that the power supply takes place in a uniform distribution across the target or target segment, and also the heat arising at the target or target segment during the coating method can be uniformly conducted away into the cooling body, by which means more power can be coupled into the coating source and the coating rate is raised.

This application claims the priority of European Patent Application No. 06405117.0, dated Mar. 16, 2006, the disclosure of which is incorporated herein by reference.

The invention relates to a target holder for a target, which is used in a coating method. The coating method includes in particular a gas flow sputtering method for the application of high temperature resistant adhesive layers on a substrate, such as in particular on a turbine blade. The target contains the coating material, which can be sputtered out of the target by means of ions of an ionised inert gas plasma. The targets are accommodated on target holders in the housing of a coating source. The coating material sputtered from the target reaches the substrate to be coated via the ionised inert gas plasma flux. The coating source is located in a closed vacuum chamber, which is continually pumped down. The ionised inert gas and the deposited coating particles of the target reach the substrate inside the chamber or are pumped off by the vacuum pump. Each target has to be mechanically fastened in the target holder, by which means stresses arise in the target. Stresses of this kind are undesirable in the target because the coating material, from which the target is made, is neither resistant to tensile stresses nor to compressive stresses, nor to torsional stresses. The coating material is, as a rule, at least partially sintered powder or melts.

A target is soldered onto a target holder, or screwed directly to the target holder. A possible solution is to drill a blind hole into the target holder in which the target is screwed. The target is exposed to a high heat input during operation. This heat has to be dissipated via the target holder however. With both a soldered connection, and also with a screwed in realisation, overheating can occur in the target, in particular in temperature ranges above 400° C., since the heat can not be dissipated via the contact surfaces of the soldered connection or of the screwed connection. Overheating of this kind results in high residual stresses occurring in the target, which lead to a formation of cracks and subsequently to premature failure of the target.

It is therefore the object of the invention to connect a target or a target segment to the cooling system by means of a target holding apparatus in such a way that overheating of this kind no longer occurs.

This object is satisfied by the characterising part of claim 1. An apparatus for the attaching of a target or target segment of a coating source includes a target or target segment and a target holder, which includes a cooling body and a connecting means for attaching the target or target segment on the cooling body. The connecting means include electrically and/or thermally conductive means, so that the current supply takes place in a uniform distribution across the target or target segment, and also the heat arising at the target or target segment during the coating method can be conducted away into the cooling body uniformly.

In the following the term target segment should also be used for target. The term target is admittedly usually used since one only uses a single target in conventional sputtering processes. Target stands for an element made of coating material, which is located in a coating source, which is used for a coating method, such as a gas flow sputtering process for example. A coating apparatus is used for the coating process, which includes the coating source, and also the substrate to be coated. The coating source includes the totality of the target segments, the target holder for each target segment, a distribution apparatus for a gas, which includes an inert gas, in particular argon or a reactive gas, in particular an oxygen-containing gas. The coating source further includes a cooling body with a coolant connection, in particular a water connection and also a housing for the accommodation of all the above-named components, and also means for isolating the whole coating source. These means for isolating effect the complete electrical isolation and the largely complete thermal isolation of the coating source from the sputtering space. The term sputtering space is used to describe the region of the coating apparatus, which is for the most part formed as a vacuum chamber, in which the coating takes place, which means that the component to be coated or the components to be coated are located in this region of the vacuum chamber. The coating material is arranged on the target segment. The coating source is used in particular in a gas flow sputtering method, for which the abbreviations GV-PVD (gas flow physical vapour deposition) or also HS-PVD (high speed physical vapour deposition) will be used in the following. For the most part two target segments lying opposite one another are used for the gas sputtering method. Depending on the size and sputter rate desired, these target segments can be designed as an single element or can comprise a plurality of individual segments, precisely the aforementioned target segments. Thus the expression target segment in this application, instead of target, means that at least one target segment is used per target holder. The segmentation of the targets permits the achievement of higher coating rates and power inputs. Should higher coating rates and power inputs be of secondary importance, the sputtering method can also be carried out without segmentation using the present arrangement of the coating source. By using target segments it is possible to input a higher electrical power into each target segment, by means of which the sputtering of layer material from the target segment is accelerated, so that a higher sputtering rate can be achieved. As a result of the higher sputtering rate, higher coating rates result on the component. The use of target segments also offers advantages, which concern the durability and mechanical characteristics of the target segments. Due to the low stresses in each target segment, cracks and breaks in the coating material do not arise. Thus hard and/or brittle coating materials, such as, in particular, MCrAlY, can be subjected to the same power input, without an alteration in the handling of the coating materials during installation and during the coating method being necessary. Very soft materials, in particular pure aluminium or magnesium, which can only be soldered badly or even not at all, can be used with the same power input, without an alteration in the handling of the coating materials during installation and during the coating method being necessary. Furthermore the temperature resistance of the arrangement of the target segments increases, because the heat can be conducted away in an improved manner, through which no material melts on any of the target segments. Each of the target segments has in particular its own power connection and also its own connection to the cooling body. The primary function of the cooling body is to conduct away the heat occurring during the coating method. The thermal energy to be conducted away is produced by the power input, which is caused by currents of in particular up to 150 A per target, and in particular creates power densities of in particular up to 220 W/cm² on the target surface, and also by the impact of the gas atoms striking the target segment. An inert gas can be used on the one hand in a coating method for coating with a metallic coating material, and argon in particular has proved to be suitable. The impact energy of these argon atoms likewise leads to a heat input into the target element. By means of the impact, atoms of the coating material are released from their bond at the target surface. During this high temperatures are reached. In order to control the process, it can be heated additionally by means of a radiative heating apparatus in order to reach coating temperatures, depending on the substrate and the layer, of up to approximately 1150° Celsius in the coating chamber. The coating apparatus can also be used for a reactive gas flow sputtering method. Instead of or in addition to inert gas, reactive gas, in particular oxygen-containing gas is added, by which means reactions of the coating material with the gas molecules at the target segment or in the gas phase after separation from the target segment result, so that a rise in temperature occurs, through the mostly exothermally occurring chemical reactions, in particular oxidation reactions. In order to avoid overheating of the target segment in a coating time of several hours, each target segment is cooled, wherein in particular water cooling is used. For the coupling in of higher currents, which result in higher heat transfer at the target segment, it is advantageous to use a plurality of individual target segments in the coating apparatus. In order to avoid the above-mentioned stresses in the target segment or to reduce them until they are below the crack formation stress of the target segment material, the target holder described in the following is used.

The coating source thus includes the target segment or target segments, the power connection for each of the target segments, a connection of each of the target segments to the cooling system for the supply and discharge of a coolant. The supply of the inert gas and/or of the reactive gas takes place via gas connections, and also gas distributors, which are arranged in such a way that a uniform distribution of the quantity of gas takes place with a same mean impact speed on all target segments. Apparatus-wise each target segment is accommodated in a target holder. The target holder includes the cooling body or bodies, and also an outer wall and connection connection means for connecting the target segment to the cooling body and also the outer wall of the coating source. By means of the previously described construction of the coating source, target segments and also other parts of the coating source, such as the gas distribution unit, the receiving units for coating material, which was not transported out of the coating source by the stream of gas can be installed and removed independently of one another, so that an improved repair and cleaning of the target segments, and also other parts of the coating source can be achieved. This fact is of particular significance in high power applications and long-term use of the coating source. If damage should occur to a target segment, which leads to a break down of the coating source, it is possible to repair the damage quickly by the exchange of the target segment. This results in a cost advantage because all other target segments can still be used further. The proportion of no longer usable coating material includes at most the coating material of the target segment to be replaced. The time needed for the exchange of the target segment is reduced, since only the damaged target segment is to be exchanged and each target segment can be exchanged individually by means of the target holder in accordance with the invention. Each component of the target holder is likewise exchangeable independently of the remaining parts of the coating source. One consequence of this service friendliness is the reusability of the target holder and/or of the target segments during their entire life. The breakdown of a target holder and/or of a target segment only results in a short standstill time of the coating plant, causing, at the most, slight interruptions in production, particularly in series production applications. Coating tasks can also be realised using different coating materials in the same coating plant due to the exchangeability of the target segments. The target segments can be constructed from any desired coating materials, so that a target can have target segments of different coating materials. The conversion of the whole target to a new coating material is comparatively unproblematic by means of the target holder in accordance with the invention, since the targets can be exchanged quickly. The dimensions of the target segments can likewise vary in many areas, so that the composition of the coating on the component can be adjusted precisely by means of the dimensioning of the target segments, the arrangement of the target segments, and the variation of the gas distribution by displaceable gas distribution units or a change of the through flow in the gas distribution unit.

Further advantageous embodiments of the invention are the subject of the subsidiary claims. The apparatus includes a T-nut for accommodating an attachment screw for the connection of the target segment to the cooling body.

The T-nut and/or the attachment screw have a contact lamella, and a power and heat conducting contact can be established between the T-nut and the attachment screw and/or the target segment by means of the contact lamella.

The T-nut has a galvanic coating in the contact region of the T-nut with the attachment screw and/or the T-nut and the cooling body and/or the T-nut and the target segment. The cooling body and/or the target segment have a galvanic coating at least on the common contact surfaces.

The attachment screw is surrounded by a sleeve in the region of the through bore through the cooling body, and the sleeve can be formed as a hollow cylindrical body, which includes, in particular, an external screw thread, with which the sleeve can be screwed into a bore in the cooling body and through which the attachment screw can be inserted through with an accurate fit, or the sleeve can be screwed into a threaded hole of the cooling body together with the attachment screw, so that a good heat transfer from the attachment screw into the cooling body takes place for the conducting of the heat away from the target segment. The sleeve is also termed as a screw in lamella or a screw in lamella sleeve in technical terminology.

The electrically and/or thermally conductive means include a forked plug device for the plugging of a target segment into the cooling body.

A contact lamella is arranged between the target segment and the cooling body, in particular inside the forked plug device and/or in a recess of the cooling body and/or of the target segment adjoining the cooling body and/or of the T-nut arranged between the cooling body and the target segment.

The contact lamella includes a spring element, through which the heat transfer between the adjacent surfaces of the cooling body and/or of the target segment and/or of the T-nut and/or of the forked plug device can be improved.

The forked plug device is soldered onto the cooling body and/or plugged in a recess of the target segment and/or can be screwed to the cooling body. At least one coolant passage is provided for the conveying of the coolant through the cooling body. The cooling body includes at least one inlet and one outlet for the coolant, so that the coolant can be conveyed from the inlet through the coolant passage to the outlet. Water is used in particular as a coolant.

A receiving means is provided in the cooling body for connecting means, in particular for the attachment screw and/or the forked plug device and/or the target segment and the coolant passage is arranged around the receiving means.

The receiving means include bores for the attachment screw and/or sleeve and/or recesses for the target segment and/or a forked plug device.

The coolant passage is formed as an open coolant passage, which was manufactured by means of a chip forming machining process or by means of a chemical process, in particular an etching process. The open coolant passage is bounded by an exterior wall of a cooling body, wherein cooling body and cooling body exterior wall are soldered, brazed, bolted or secured by a clamping connection and sealing means are provided between the cooling body and the cooling body exterior wall, in order to prevent the escape of coolant from the cooling body.

The cooling body contains at least one bore for a screw head of the attachment screw, with the attachment screw being guided through the cooling body exterior wall and through the cooling body in order to be screwed in the T-nut with the internal thread of the bore.

The coolant passage in the cooling body is arranged in such a way that the bores are arranged in the cooling body base material and/or a sleeve is arranged in the bore, with the sleeve being directly or indirectly in heat conducting contact with the coolant.

Receiving means for the target segment and/or the forked plug device are provided at the inside of the cooling body, with the receiving means being designed as soldering or brazing points or as recesses.

A plurality of target segments is provided in the coating source, which can be secured in the target holder via electrically or thermal conductive means.

The T-nut, the contact lamellae and/or the sleeve and/or the forked plug device contain a copper and/or nickel alloy, in particular a copper and beryllium containing alloy or a copper and beryllium and cobalt containing alloy.

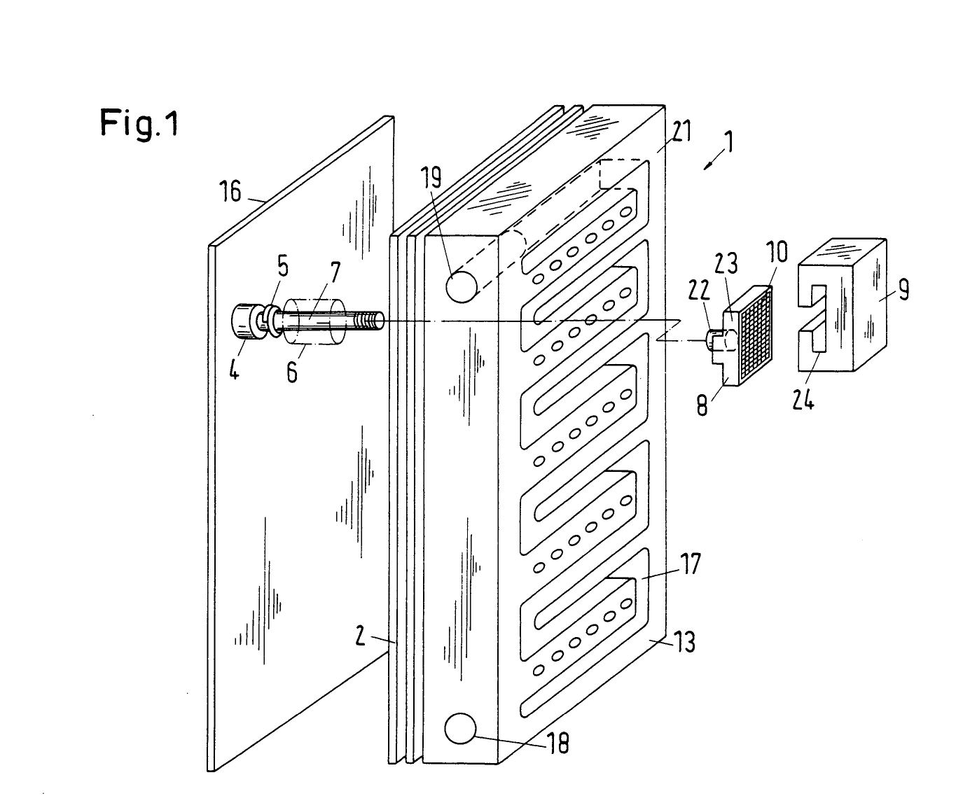

FIG. 1 shows a combination of a target holder in accordance with a first embodiment

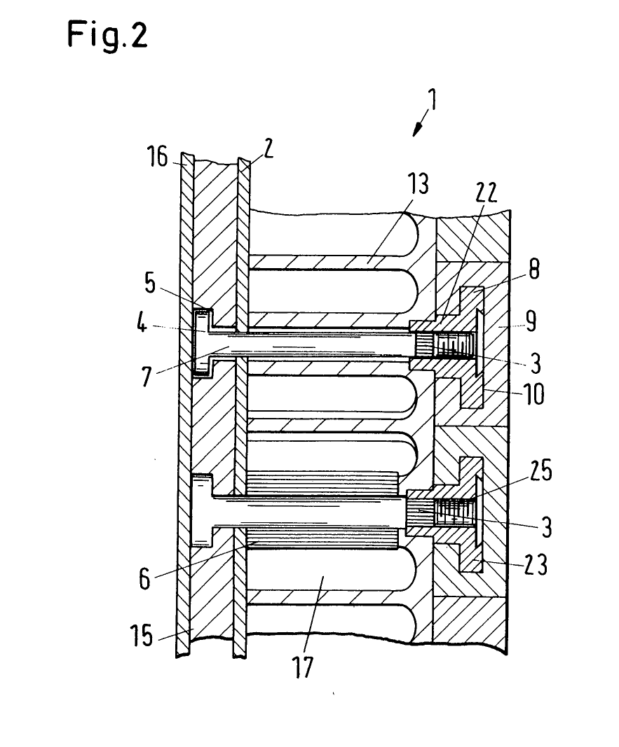

FIG. 2 shows a section through the target holder in accordance with FIG. 1

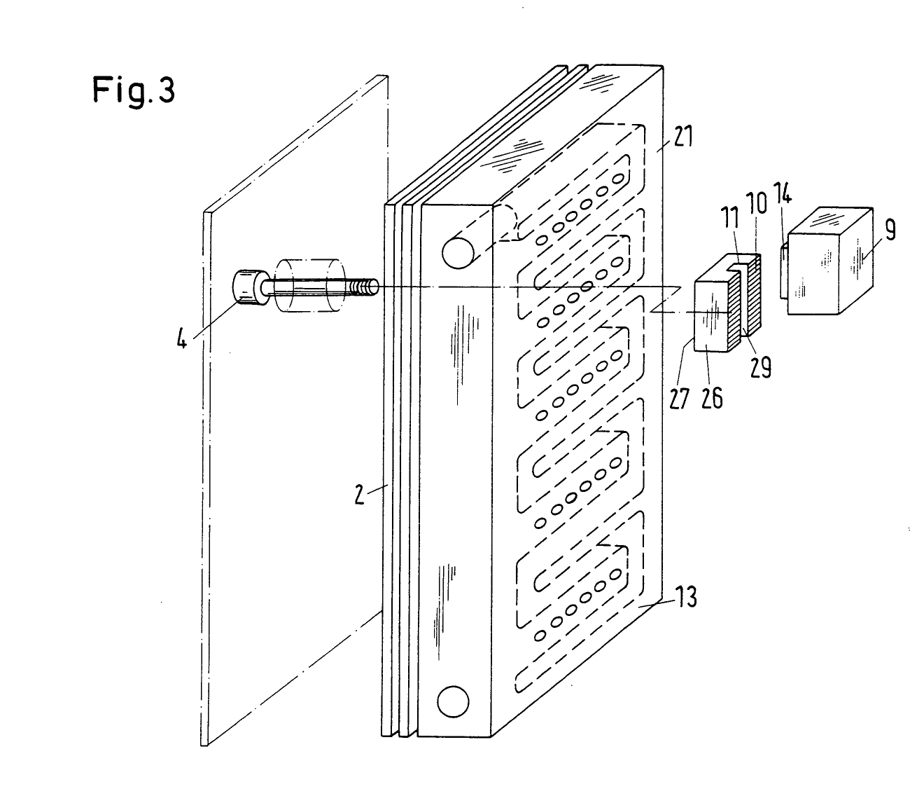

FIG. 3 shows a combination of a target holder in accordance with a second embodiment

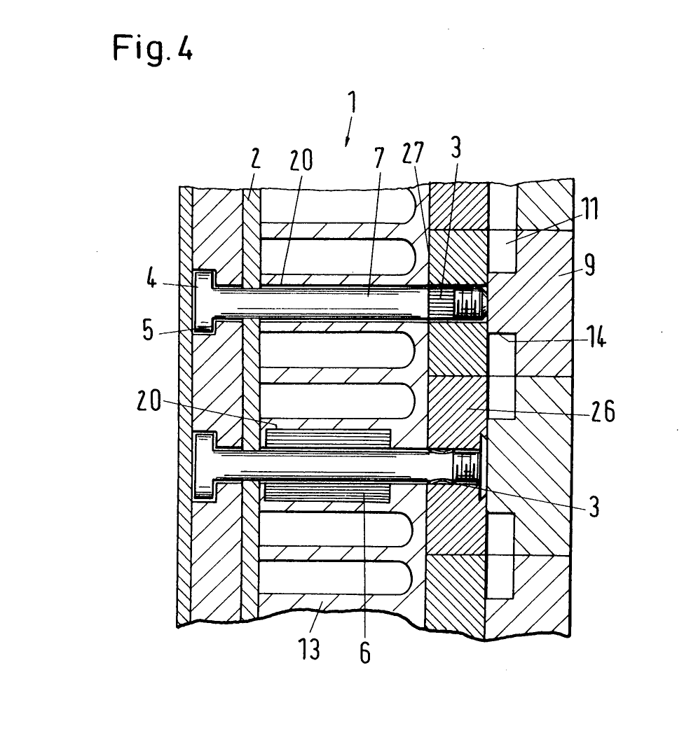

FIG. 4 shows a section through the target holder in accordance with FIG. 3

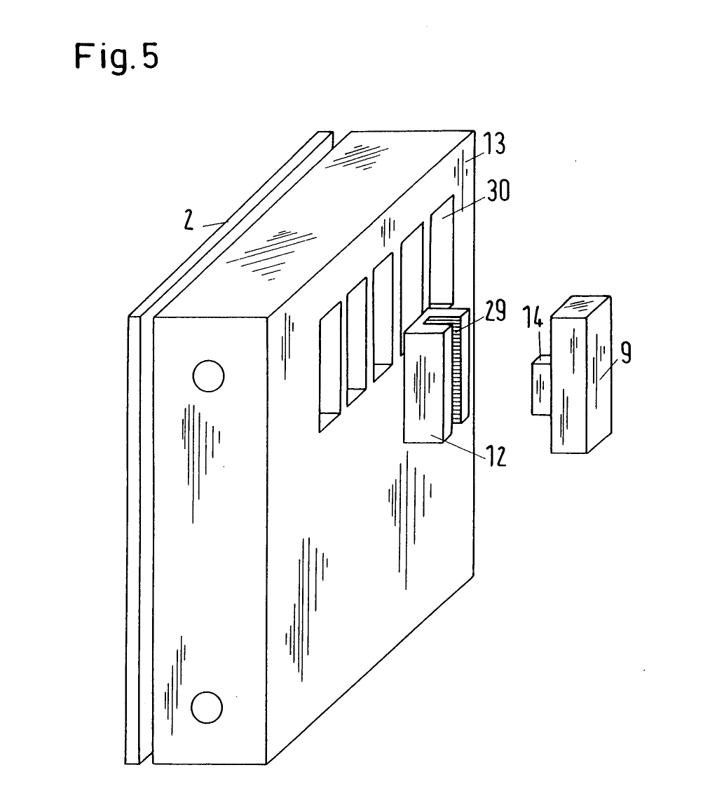

FIG. 5 shows a combination of a target holder in accordance with a third embodiment

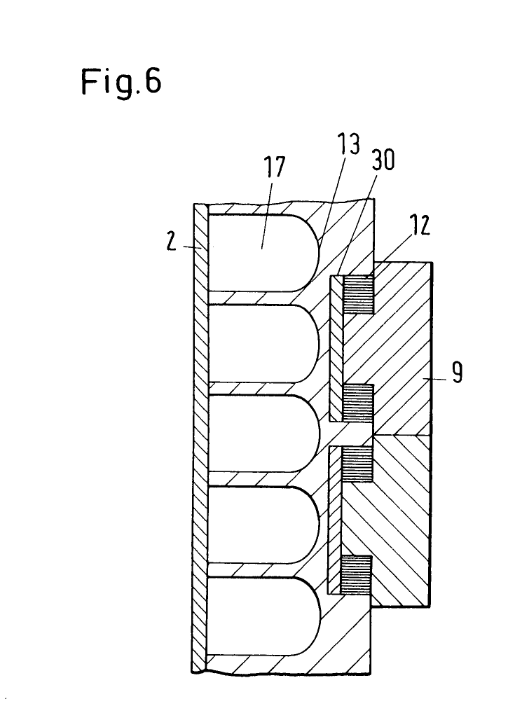

FIG. 6 shows a section through the target holder in accordance with FIG. 5

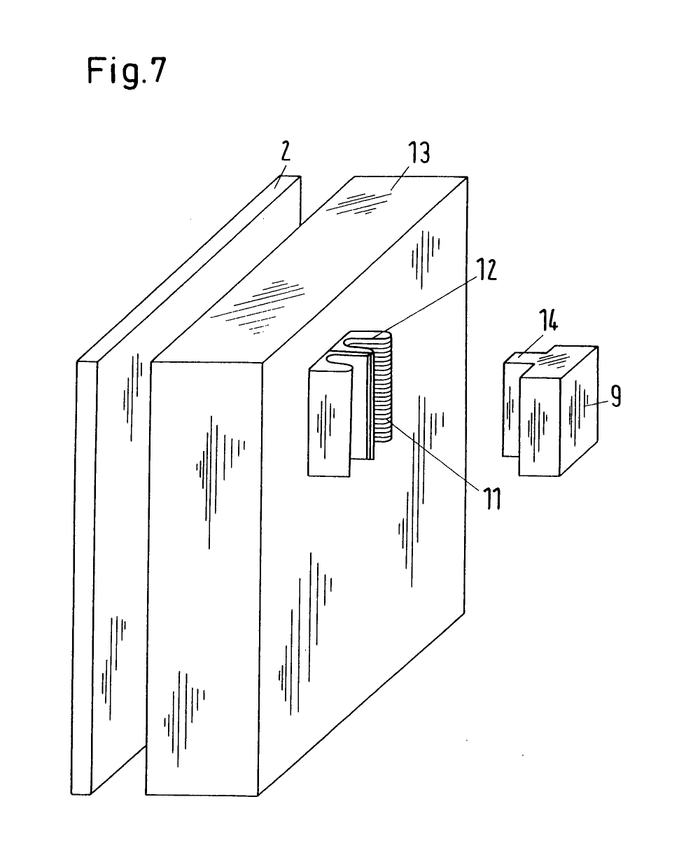

FIG. 7 shows a combination of a target holder in accordance with a fourth embodiment

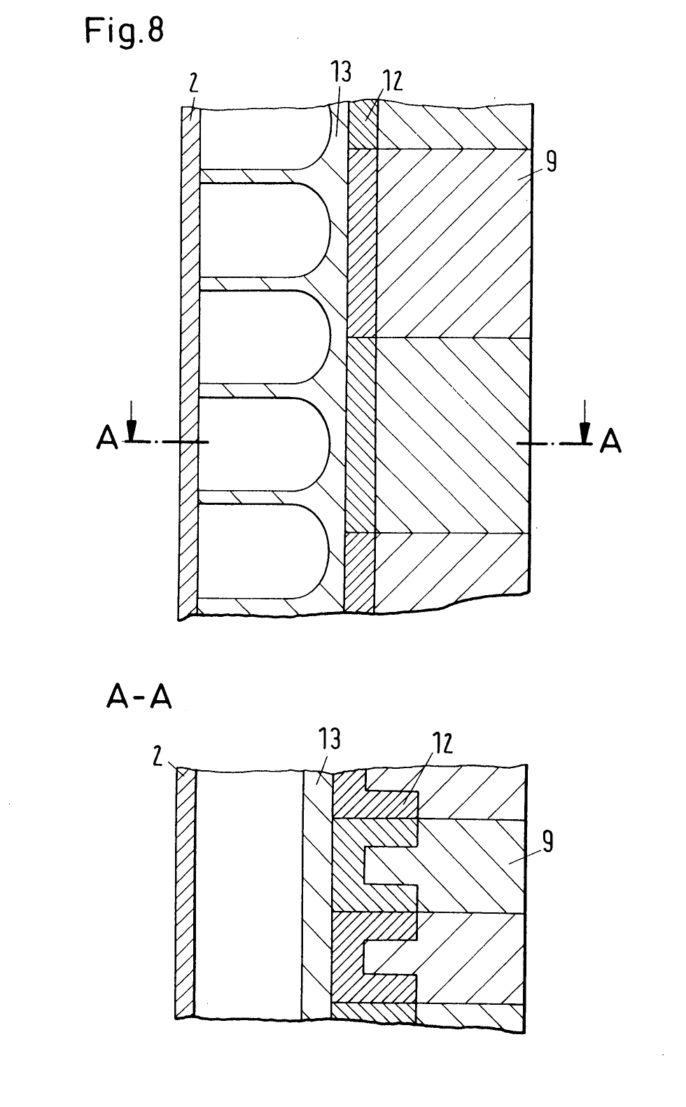

FIG. 8 shows a section through the target holder in accordance with FIG. 7

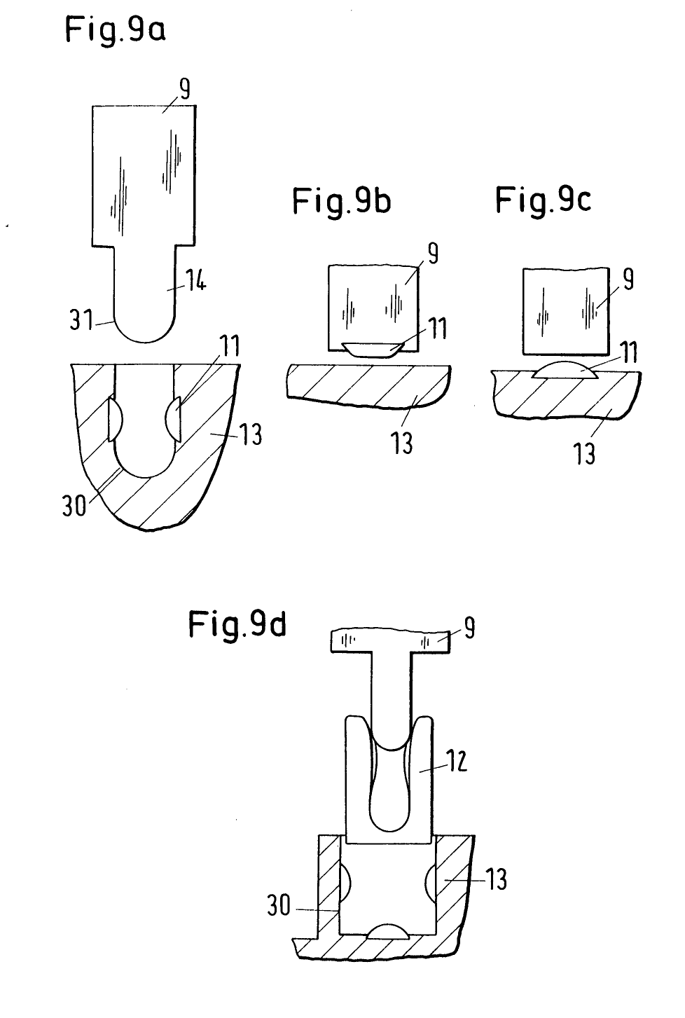

FIG. 9a shows a further variant for the connection of the target segment with the cooling body

FIG. 9b shows a further variant for the connection of the target segment with the cooling body

FIG. 9c shows a further variant for the connection of the target segment with the cooling body

FIG. 9d shows a further variant for the connection of the forked plug device with the cooling body

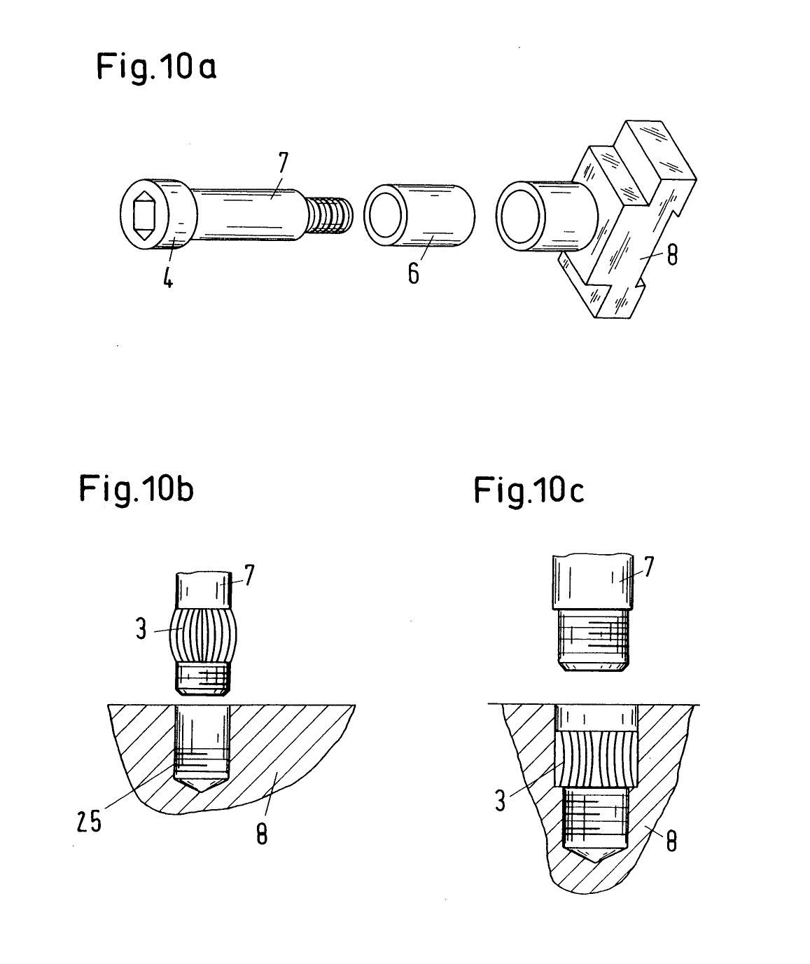

FIG. 10a shows the T-nut, the sleeve and the attachment screw in accordance with FIGS. 1 to 4

FIG. 10b shows a first variant for the connection of the attachment screw with the T-nut

FIG. 10c shows a second variant for the connection of the attachment screw with the T-nut

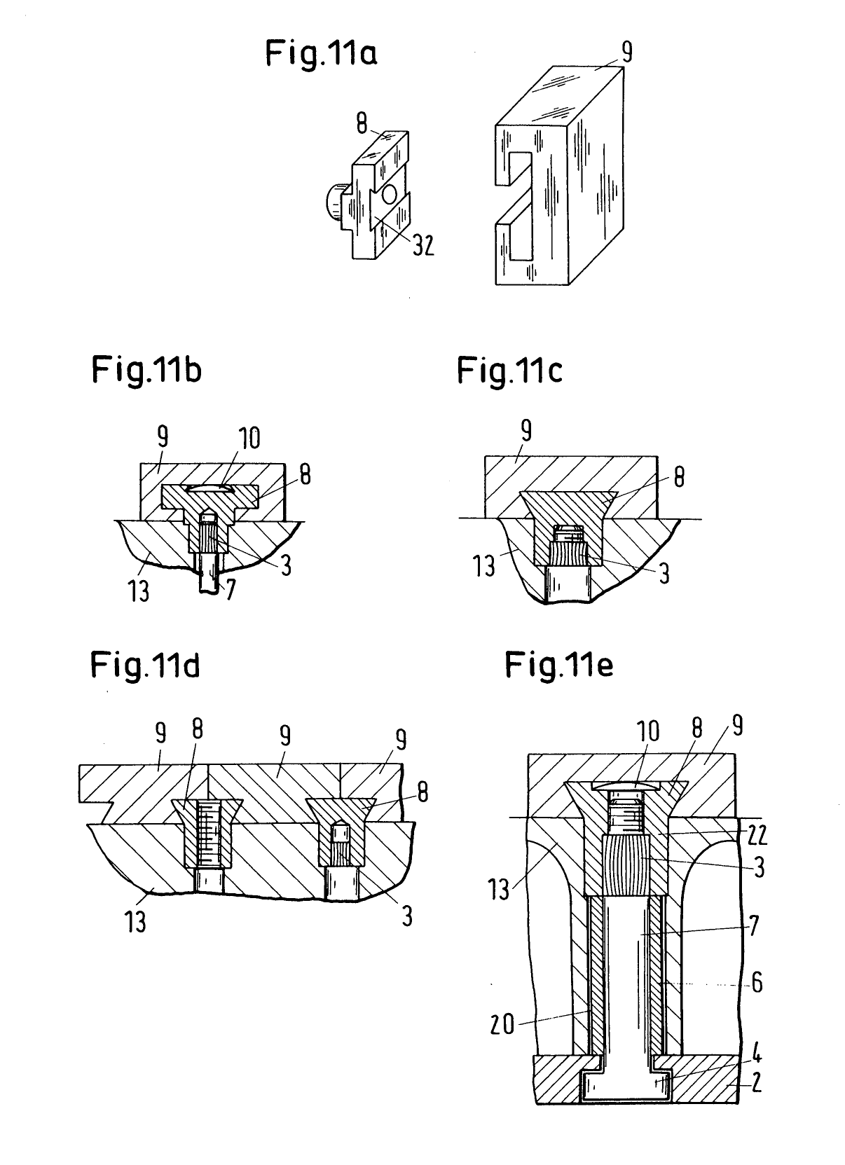

FIG. 11a shows the connection of the target segment with the T-nut

FIG. 11b shows a section through a first embodiment of a connection of the target segment and the T-nut.

FIG. 11c shows a section through a second embodiment of a connection of the target segment and the T-nut.

FIG. 11d shows a section through a third embodiment of a connection of the target segment and the T-nut.

FIG. 11e shows a section through a fourth embodiment of a connection of target segment and the T-nut.

FIG. 1 shows the arrangement of a target segment 9, which is secured in the coating source to a target holder 1. Each target segment 9 is screwed to the cooling body outer wall 2 by means of a T-nut 8. The T-nut includes a cylinder 22 and a continuation 23, which has a T-shaped cross-section. The cylinder 22 is received by a bore in the cooling body 13. The T-shaped continuation 23 projects beyond the surface of the inside of the cooling body 21. A contact lamella 10 of low-alloy copper or nickel, in particular of CuBe, CuCoBe or NiBe is attached to the T-nut and/or a galvanic coating is applied. At least one target segment 9 is plugged onto the T-nut 8, with the T-nut and the target segment having an intermediate space in which the contact lamella 10 is arranged. In FIG. 1 the target segment 9 is plugged onto the T-shaped continuation 23. A groove 24 is provided in the target segment, which is broadened into the shape of a T, which is designed to match the shape of the continuation 23. The T-shaped continuation 23, which engages into an associated groove 24 of the target segment 9, can serve to receive at least one target segment 9. A possible variant in which a T-shaped continuation 23 serves for receiving a plurality of target segments 9 is not illustrated. One target is pushed into its position on the T-shaped continuation 23 in the same way as the target segments already plugged into place, with the number of the target segments per T-nut being dependent on the width of the segment, which in turn is in direct relation to the source size. The target segments are all plugged onto the T-nuts and/or associated contact lamellae and/or associated galvanic coatings. Each of the target segments 9 is in a counter-shape corresponding to the shape of the continuation 23, with a groove in the form of a T being shown in FIG. 1. However, other form-locked or shape-matched connections can be used, by means of which the T-nuts and/or the contact lamellae can be surrounded, at least in part. In particular, a dovetail groove can be provided in the target segment 9. The contact lamellae and/or the galvanic coatings conduct the heat from the target segment in the direction of the cooling system by means of their good heat conducting characteristics. For the improvement of the heat transfer from the target segment 9 to the contact lamellae 10, a galvanic coating can also be provided on the contact lamellae. The galvanic coating is in particular located on the surface of the contact lamellae 10 facing the target segment or segments 9. The ions of an inert gas impact on the target segment in operation, in other words during the coating process. They knock atoms out of the target segment material. By means of the impacts of the ions striking on the target segment material thermal energy is carried into the target segment 9, which is carried off to the cooling body 13 via the contact lamellae 10, the T-nut 8 and also the attachment screw 7. In FIG. 2 the target holder 1 from FIG. 1 is illustrated in section. In FIG. 2 the attachment screw 7 is only illustrated in the upper part of the drawing, in the lower part the attachment screw 7 is left out, in order to increase clarity. An internal thread 25 is located inside the part of the T-nut 8 formed in particular as a cylinder 22, as illustrated in FIG. 2. The external thread of the attachment screw engages into the internal thread 25. The attachment screw consists in particular of copper or low alloy copper, such as CuBe, CuCoBe, CuTeP. As a modification of the upper part, the lower part of FIG. 2 shows the installation of a sleeve 6. This sleeve 6 is additionally used for the removal of the thermal energy to the cooling body and is also termed as a screw-in lamella or screw-in lamella sleeve in specialist literature. The chief function of the sleeve 6 is to improve thermal and electrical contact between the attachment screw 7 and the cooling body 13. The sleeve 6 is screwed into the cooling body 13 or plugged onto it so that a good heat transfer is guaranteed by the connection, which is designed in particular as a screw connection or as a press fit.

The connection of the target segment 9 to the cooling body 13 and to the power contact which is not illustrated is achieved here by means of the contact lamellae 10 between the target segment 9 and the surface of the continuation 23 on the target segment side, by means of the rear side target segment surface of the target segment 9, of the T-nut 8, via the T-nut, via the internal thread 25 of the cylinder 22 of the T-nut, and also of one contact lamella 3 arranged in the internal thread 25, into the attachment screw 7 and also from the attachment screw 7 directly to the cooling body or alternatively to this via the sleeve 6 to the cooling body 13. The contact lamella 3 is either part of the attachment screw 7, as is illustrated in the upper part of FIG. 2, or is part of the cylinder 22 of the T-nut 8, as is illustrated in the lower part of FIG. 2. The sleeve 6 is illustrated in FIG. 2 with direct contact to the coolant, which flows through the cooling passages 17. The insulation of the coating source against discharges to the outer sides takes place by means of an insulating zone 16. The insulating zone 16 is located on the outer wall 15, which also contains recesses for the screw heads 4 of the attachment screws 7.

In a further embodiment in accordance with FIG. 3 and FIG. 4, the connection of the target segment 9 to the cooling body 13 and to the power contact, which is not illustrated, is effected by means of a connector 26. The connector 26 contains an internal thread 28 at its surface on the cooling body side, which serves to receive an attachment screw 7, which is formed identical to the attachment screw from the embodiment in accordance with FIG. 1 or FIG. 2. The connector 26 includes a contact lamella 27 and/or a galvanic coating for increasing the current and/or heat transfer at its surface on the cooling body side. In this arrangement the contact lamella 27 does not need to be restricted to the internal thread 27, but is able to encompass the entire contact surface. The advantage is that heat can be transferred directly from the connector 26 to the inside of the cooling body 21. The coolant passages 17, which are illustrated in FIG. 3 as a not visible element, are located in the direct vicinity of the surface of the connector 26 on the cooling body side and its contact lamella 27 and/or its galvanic coating in the illustrated variant. The contact lamellae 11 are provided in a slit-like recess 29 between the target segment 9 and the surface of the connector 29 on the target segment side. The recess 29 is used for the reception of a rib 14 of the target segment 9, which is intended for engagement into the slit-like recess 29.

In the first embodiment, the thermal transfer also takes place between the target segment 9 and the surface on the target segment side of the slit-like recess 29 via the rib 14 of the target segment, through the connector 26 via the internal thread 28 and a contact lamella 3 arranged optionally in the internal thread 28 into the attachment screw 7 and also from the attachment screw 7 directly to the cooling body or, alternative to this, via the sleeve 6 to the cooling body 13. The contact lamella 3 is either part of the attachment screw 7, as is illustrated in the upper part of FIG. 4, or is part of the internal thread 28 of the connector 26, as is illustrated in the lower part of FIG. 4. In FIG. 4 the sleeve 6 is not shown in direct contact with the coolant, which flows through the coolant passages 17. The variant of the installation of the sleeve 6 illustrated in FIG. 4 can also be applied to the embodiment according to FIG. 2. The sleeve 6 is screwed into or pressed into the cooling body. In addition receiving means 20 are provided in the cooling body, which are bores for the attachment screw 7 and/or the sleeve 6. As an alternative the sleeve can also have a fixed connection to the attachment screw 7, i.e. a screw connection or comparable shape matched or form locked connection or a pressed connection. A forked plug device 12 can also be received in the slit-like recess 29, as will be described in the following embodiments. The forked plug device 12 includes in particular a slit-like recess which contains contact lamellae at its inside.

In a further embodiment in accordance with FIG. 5 the target holder 1 is simultaneously formed as a cooling system. The target holder 1 includes the cooling body 13 in which grooves 30 are located, into each of which at least one forked plug device 12 can be received. The cooling body 13 comprises a good thermally and electrically conductive material, such as in particular copper or low alloy copper. The forked plug device 12 is provided with contact lamellae 11, which likewise consist of material with good thermal and electrical conductivity, in particular low alloy copper. The contact lamellae 11 can be galvanically coated for the reduction of the contact resistance. A contact resistance of this kind is always present between the surfaces bordering on one another of two directly adjacent bodies lying next to one another two-dimensionally, particularly if these are bodies made of different materials, as are the target segment and the target holder in this case. A reduced thermal transfer takes place at a boundary surface of this kind due to the surface roughness and the distances to the oppositely disposed surface caused by this, which can be improved by the galvanic coating i.e. by the filling up of this surface roughness. The T-nuts and the attachment screws are left out in the present embodiment as is shown in FIG. 6. The rib 14 of the target segment 9 does not extend across the whole height of the target segment in FIG. 5 or FIG. 6. It is possible to provide further connecting means in the intermediate spaces, which are not shown individually. Thus conical sliders, eccentric shafts, locking devices by means of plug contacts, tension springs or pneumatically operating plates can be used in order to guarantee a good retention of the target segment 9 in the forked plug device 12. Alternatively the possibility also exists of providing one of the aforementioned connecting means or a combination of the same instead of the forked plug device 12, so that the target segment is attached in the cooling body 13 itself.

According to a further embodiment in accordance with FIG. 7 and FIG. 8 the target segments can be plugged directly to the cooling body 13. In the case of certain materials this necessity arises for reasons of machinability. Additionally the processing costs can be reduced by the design of the plug connection, and the material costs can be reduced and the installation can be simplified. The connection of the target segments to the cooling body and the power connection take place directly via the machined ribs 14 by means of forked plug devices 12. The attachment of the forked plug devices 12 to the cooling body takes place, in contrast to the previous embodiment, not by plugging into grooves of the cooling body but by means of a bonded connection, such as for example an adhesive connection. Contact lamellae 11, so-called forked plug lamellae are inserted into the forked plug devices 12. It is also possible as an alternative to either braze or screw the forked plug devices onto the cooling body or to machine them out of the cooling body by means of a chip-forming machining process such as milling.

The target segments are plugged and fixed directly into these forked plug devices. The target segments are machined using suitable machining methods (according to material: e.g. EDM, milling) in such a way that their rib fits precisely and with firm contact into the forked plug device 12 of the cooling body 13. Milling or EDM (electron discharge machining) are used in particular as machining methods. Electron discharge machining is a high precision machining process, by means of which material is cut or drilled. A machining of even extremely hard, tough or brittle material types is made possible by means of electro-physical vaporisation by the application of an electrical potential to an electrode.

In accordance with any one of the previous embodiments the target segments 9 can be plugged into place and can also be removed again in this manner. Individual target segments can thus be replaced in all versions completely independently from the other target segments. A large effective thermal transfer surface results by means of the areal contact from the target segments to the forked plug devices, so that the target holder is directly connected to the cooling system. The heat arising in the target segment can then be dissipated simply, so that a high cooling rate can be achieved.

FIG. 9a shows a further variant for the connection of the target segment 9 to the cooling body 13. A groove 30 is located in the cooling body 13, in which a rib 14 with a rounded surface 31 engages with positive locking. Contact lamellae 11 are arranged in the groove 30. The contact lamellae 11 improve the retention of the target segment 9 in the groove 30 and permit a precise fitting of the two parts. Additionally, a galvanic coating and/or a thermally conductive, viscous or pasty fluid can be inserted in the groove for the improvement of the thermal transfer prior to the assembly of the target segment with the cooling body. This is advantageously a releasable connection, so that a used target segment can simply be exchanged.

FIG. 9b shows that a contact lamella 11 can also be attached to the target segment 9 itself. The attaching of the target segment 9 to the cooling body is not shown. A contact lamella of this kind can be used in each of the embodiments in accordance with FIG. 1 to FIG. 8.

FIG. 9c shows that a contact lamella 11 can be attached to the surface of the cooling body 13. The attaching of the target segment 9 to the cooling body 13 is not shown. A contact lamella of this kind can be used in each of the embodiments in accordance with FIG. 1 to FIG. 8. In FIG. 1 or FIG. 2 a thermal transfer in addition to the thermal transfer via the T-nut 8 and the attachment screw 7 is effected by the application of a contact lamella of this kind in the regions of the target segment which border directly on the cooling body 13.

FIG. 9d shows a combination of the rib 14 shown in FIG. 9a with a forked plug device 12, which can be arranged according to any one of the FIGS. 5 to 8. Contact lamellae can be applied to the base of the groove or to each of the walls of the groove 30. The use of contact lamellae in the forked plug device can be undertaken independently of the arrangement illustrated in FIG. 9d.

FIG. 10a shows the T-nut, sleeve and attachment screw in accordance with the embodiments from FIGS. 1 to 4 in an exploded view. In this case the sleeve 6 is plugged onto the attachment screw 7, before the assembly with the not illustrated cooling body and the T-nut 8 takes place.

FIG. 10b shows a first variant for the connection of the attachment screw to the T-nut. The T-nut 8 is shown in section, with details such as the illustration of the cylinder 22, being omitted. In the present case a blind hole with a thread was used. As an alternative the possibility exists of providing a through bore in the T-nut 8, such as was shown in FIG. 2 and FIG. 4. The choice chiefly depends on the size of the T-nut used and the time required for the removal of the material. The tip of the attachment screw 7 has a contact lamella 3, which adjoins the external thread for screwing the attachment screw 7 into the internal thread 25 of the T-nut.

A second variant for connecting the attachment screw 7 to the T-nut 8 is illustrated in FIG. 10c. In contrast to FIG. 10b a contact lamella 3 is arranged in the blind bore of the T-nut 8. The external thread of the attachment screw 7 is of a smaller diameter than the screw neck, so that the thread can not be damaged by the contact lamella 3. It can also be advantageous in the variants illustrated in FIG. 10b or 10c to introduce a thermally conductive viscous fluid into the region of the thread in order to improve the thermal transfer in the region of the thread.

FIG. 11a again schematically shows the connection of the target segment 9 to the T-nut 8 in accordance with FIG. 1 or FIG. 2. The recess 32 is used for the reception of a contact lamella 10.

FIG. 11b shows the use of a blind hole after the embodiment of FIG. 10b and the installation of a contact lamella 10 in the recess 32 for improvement of the heat transfer from the target segment 9 to the T-nut 8.

FIG. 11b shows the use of a dovetail groove 24 as a groove in the target segment. The head of the T-nut has a cross-section, which corresponds precisely to the dovetail groove in the target segment, so that a precise fit of the two parts results. Moreover, the connection of the attachment screw to the T-nut illustrated in FIG. 10c is illustrated in FIG. 11b.

FIG. 11c shows a variant for the attachment of the target segments 9 to a T-nut with a head with a design for the fitting into a dovetail groove of the target segment. One T-nut is, however, used for each of two adjacent target segments. This solution is particularly advantageous when the target segment material is not suitable for the manufacture of partially hollow structures, such as T-shaped grooves or dovetail grooves. Target segment material has to be removed exclusively from respectively two edges of the target segment, which simplifies the machining of the target segment considerably.

Two variants of the connection of the T-nut to the attachment screw 7 are also illustrated in FIG. 11d, one variant with a through bore is illustrated on the left-hand side, one variant with a blind hole in the T-nut is illustrated on the right-hand side. A contact lamella 3 is shown by way of example. Contact lamellae in accordance with FIG. 9a or FIG. 9b can be used in the arrangement shown in FIG. 11d in the same manner.

FIG. 11e shows a sectional view corresponding to FIG. 2 of a T-nut 8 with a dovetail head. A contact lamella 10 is located between the target segment 9 and the T-nut. The T-nut has a centrally arranged through bore for receiving an attachment screw 7. The attachment screw 7 partially has a contact lamella 3 in place of a thread in the region of the T-nut, which is arranged in a bore of the T-nut. The T-nut extends at least with its cylinder 22 into the cooling body 13, in which it is received. The sleeve 6 adjoins the T-nut, which serves to improve the thermal transfer from the attachment screw to the cooling body wall. The sleeve 6 is received in a receiving means 20 in the cooling body. The screw head 4 of the attachment screw is located in a bore of the cooling body outer wall 2, which closes off the inner space of the cooling body in fluid tight manner.

### REFERENCE NUMERAL LIST

1. Target Holder
2. Cooling Body Outer Wall
3. Contact Lamella
4. Screw head of the attachment screw
5. Plate Spring
6. Sleeve
7. Attachment Screw
8. T-nut
9. Target Segment
10. Contact lamella for the T-nut
11. Contact lamella for the target segment
12. Forked Plug Device
13. Cooling Body
14. Rib
15. Outer Wall
16. Insulating Zone
17. Coolant Passage
18. Inlet Coolant
19. Outlet Coolant
20. Receiving Means
21. Inner side of the cooling body
22. Cylinder of the T-nut
23. Continuation
24. Groove in the Target Segment
25. Internal thread T-nut
26. Connector
27. Contact Lamella
28. Internal Thread Connector
29. Slit-Like Recess
30. Groove
31. Rounded Surface
32. Groove

1. An apparatus for the attachment of a target or target segment (9) of a coating source including a target or target segment (9) and a target holder (1) which includes a cooling body (13) and a connecting means (6,7,8,11) for the attachment of the target or target segment to the cooling body, characterised in that the connecting means (3,6,7,8,10,11) include electrically and/or thermally conductive means, so that the power supply takes place in a uniform distribution across the target or target segment, and also the heat arising at the target or target segment during the coating method can be uniformly conducted away into the cooling body.

2. An apparatus in accordance with claim 1, including a T-nut (8) for accepting an attachment screw (7) for the connection of the target segment to the cooling body (13).

3. An apparatus in accordance with claim 2 wherein the T-nut and/or the attachment screw (7) have a contact lamella (3), wherein a power and heat conducting contact can be established between the T-nut and the attachment screw and/or the target segment (9) through the contact lamella (3).

4. An apparatus in accordance with claim 1 wherein the T-nut has a galvanic coating in the contact region of the T-nut with the attachment screw and/or the T-nut and the cooling body and/or the T-nut and the target segment and/or wherein the cooling body (13) and/or the target segment (9) has a galvanic coating at least at the common contact surfaces.

5. An apparatus in accordance with claim 1, wherein the attachment screw (7) is surrounded by a sleeve (6) in the region of the through bore through the cooling body, wherein the sleeve can be formed as a hollow cylindrical body, which includes in particular an external screw thread, with which the sleeve can be screwed into a bore in the cooling body and through which the attachment screw can be inserted with an accurate fit, or wherein the sleeve can be screwed into a threaded bore of the cooling body together with the attachment screw, so that a good heat transfer takes place from the attachment screw into the cooling body for the conduction of heat away from the target segment.

6. An apparatus in accordance with claim 1, wherein the electrically and/or thermally conductive means include a forked plug device (12) to plug a target segment into the cooling body (13).

7. An apparatus in accordance with claim 1, wherein a contact lamella (11) is arranged between the target segment (9) and the cooling body (13), in particular inside the forked plug device (12) and/or in a recess of the cooling body and/or of the target segment adjoining the cooling body and/or of the T-nut arranged between the cooling body and the target segment.

8. An apparatus in accordance with claim 7, wherein the contact lamella (11) includes a spring element, through which the heat transfer between the adjacent surfaces of the cooling body (13) and/or of the target segment (9) and/or of the T-nut (10) and/or of the forked plug device (12) can be improved.

9. An apparatus in accordance with claim 7, wherein the forked plug device (12) is soldered onto the cooling body and/or plugged into a recess of the target segment and/or can be screwed to the cooling body.

10. An apparatus in accordance with claim 1, wherein at least one coolant passage (17) is provided for the conveying of the coolant by the cooling body and the cooling body (13) includes at least one inlet (18) and one outlet (19) for the coolant, in particular water, so that the coolant can be conveyed from the inlet (18) through the coolant passage (17) to the outlet.

11. An apparatus in accordance with claim 1, wherein receiving means (20) are provided in the cooling body for connecting means, in particular for the securing screw (7) and/or the forked plug device (12) and/or the target segment (9) and the coolant passage (17) is arranged around the receiving means (20).

12. An apparatus in accordance with claim 1, wherein the receiving means include bores for the securing screw (7) and/or sleeve (6) and/or recesses for the target segment (9) and/or a forked plug device (12).

13. An apparatus in accordance with claim 1, wherein the coolant passage is formed as an open coolant passage, which was manufactured by a chip-forming machining process or by a chemical process, in particular an etching process and the open coolant passage is bounded by an outer wall (2) of the cooling body, with the cooling body (13) and the outer wall (2) of the cooling body being brazed, soldered, screwed or secured by means of a clamped connection and sealing means is provided between the cooling body and outer wall of the cooling body in order to prevent the escape of coolant from the cooling body.

14. An apparatus in accordance with claim 13, wherein the outer wall (2) of the cooling body contains at least one bore for a screw head (4) of the attachment screw (7), wherein the attachment screw is guided through the cooling body exterior wall (2) and also through the cooling body in order to be screwed to the internal thread of the bore in the T-nut (8).

15. An apparatus in accordance with claim 13, wherein the coolant passage is arranged in the cooling body in such a way that the bores are arranged in the cooling body base material and/or a sleeve (6) is arranged in the bore, with the sleeve being directly or indirectly in heat-conducting contact with the coolant.

16. An apparatus in accordance with claim 1, wherein mounts are provided for the target segment (9) and/or the forked plug device (12) on the inner side (21) of the cooling body, with the mounts being formed as brazing or soldering points or as recesses.

17. An apparatus in accordance with claim 1, wherein a plurality of target segments (9) is provided in the coating source which can be secured in the target holder (1) via electrically and/or thermally conductive means in accordance with any one of the previous claims.

18. An apparatus in accordance with claim 1, wherein the T-nut (8), the contact lamellae (3, 10) and/or the sleeve (2) and/or the forked plug device (12) contain a copper and/or nickel alloy, in particular an alloy containing copper and beryllium or an alloy containing copper and beryllium and cobalt.
